(19) United States
(12) Patent Application Publication
(10) Pub. No.: US 2022/0344556 A1
(43) Pub. Date: Oct. 27, 2022

(54) LED PACKAGE STRUCTURE, LED PACKAGING METHOD, AND LIGHT SOURCE

(71) Applicant: SHENZHEN SUNSCREEN CO., LTD., Shenzhen City (CN)

(72) Inventor: WEN-JOE SONG, Shenzhen City (CN)

(21) Appl. No.: 17/345,282

(22) Filed: Jun. 11, 2021

(30) Foreign Application Priority Data
Apr. 22, 2021 (CN) 2021104345839

(51) Int. Cl. H01L 33/62; H01L 33/00; H01L 33/50; H01L 33/52

(52) U.S. Cl. CPC H01L 33/62; H01L 33/0095; H01L 33/50; H01L 33/52; H01L 2933/0041; H01L 2933/005; H01L 2933/0066

(57) ABSTRACT

An LED package structure, an LED packaging method, and a light source are disclosed. The LED package structure includes a first surface and at least one side face adjacent to the first surface. The LED package structure further includes: a first soldering side disposed on the first surface; and a second soldering side electrically connected to the first soldering side and disposed on the side face.

### CROSS-REFERENCE TO RELATED APPLICATION

This application is filed on the basis of Chinese patent application No. 2021104345839 filed Apr. 22, 2021, and claims priority of the Chinese patent application, the entire contents of which are incorporated herein by reference.

### TECHNICAL FIELD

The present disclosure relates to an LED packaging technology, and in particular, to an LED package structure, an LED packaging method, and a light source.

### BACKGROUND

As a new light source in the 21st century, LEDs are advantageous in high luminous efficacy, low heat generation, low operating voltage, small power consumption, small size, etc., and also have advantages of feasible flat package, ease of developing thin and light products, rigid structure, and long service life. The LED light source does not contain harmful substances such as mercury and lead, is free of infrared and ultraviolet radiation pollution, and does not pollute the environment during production and use. Therefore, developing LEDs as a novel light source to replace conventional lighting fixtures becomes a general trend in consideration of electric energy saving, reduction of greenhouse gas emission, and decrease in environmental pollution.

At present, as LEDs are developing towards miniaturization, LED package structures have small soldering areas, and consequently the LED package structures are easily subjected to poor soldering, or even easily fall off after soldering.

### SUMMARY

The present disclosure is intended to solve at least one of technical problems in the existing technologies. In this regard, the present disclosure provides an LED package structure, such that a wetting effect of the LED package structure can be improved, and the problem of insufficient package soldering strength caused by a small size and a small soldering area of the package structure can be solved.

According to a first aspect, an embodiment of the present disclosure provides an LED package structure, including a first surface and at least one side face adjacent to the first surface.

The LED package structure further includes:

a first soldering side disposed on the first surface; and

a second soldering side electrically connected to the first soldering side and disposed on the side face.

In an optional implementation, the LED package structure further includes a substrate and an LED chip; where

the substrate includes a first circuit layer, an insulating layer, and a second circuit layer, the first circuit layer is on the first surface, the second circuit layer is on a second surface, and the insulating layer is between the first circuit layer and the second circuit layer;

the LED chip is disposed on the second circuit layer and is electrically connected to the second circuit layer; and

the substrate further includes a first groove body, and the first groove body is filled with a conductive material; the conductive material is exposed at the first surface to form the first soldering side, or the conductive material is exposed at the first surface and is electrically connected to the first soldering side; and the conductive material is exposed at the side face to form the second soldering side, or the conductive material is exposed at the side face and is electrically connected to the second soldering side.

In an optional implementation, the LED package structure further includes:

a (2N−1)^{th} soldering side disposed on the first surface; and

a (2N)^{th} soldering side disposed on the side face;

where N is a positive integer greater than or equal to 2.

In an optional implementation, the substrate further includes:

an N^{th} groove body, where the first groove body is filled with a conductive material; the conductive material is exposed at the first surface to form the (2N−1)^{th} soldering side, or the conductive material is exposed at the first surface and is electrically connected to the (2N−1)^{th} soldering side; and the conductive material is exposed at the side face to form the (2N)^{th} soldering side, or the conductive material is exposed at the side face and is electrically connected to the (2N)^{th} soldering side.

In an optional implementation, the conductive material includes one or more of copper, silver, gold, palladium, and tin.

In an optional implementation, the LED package structure further includes:

an encapsulant covering the LED chip.

In an optional implementation, the first circuit layer is provided with a first circuit, and the second circuit layer is provided with a second circuit; and the conductive material connects the first circuit to the second circuit.

According to a second aspect, an embodiment of the present disclosure provides a method for manufacturing an LED package structure, including:

drilling holes in a substrate to obtain a plurality of conductive holes;

filling the conductive holes with a conductive material, so that the conductive material is exposed at a first surface of the substrate to form a first soldering side;

processing a conductive layer on the substrate to form a second circuit layer;

attaching an LED chip on the second circuit layer and connecting the LED chip to the second circuit layer; and

cutting the substrate to expose the conductive material from a side face of the LED package structure to form a second soldering side.

In an optional implementation, after attaching an LED chip on the second circuit layer, the method further includes:

covering the LED chip with a transparent or semi-transparent encapsulant or a fluorescent encapsulant.

According to a third aspect, an embodiment of the present disclosure provides an LED light source, including at least one LED package structure according to the first aspect.

Some additional aspects and advantages of the present disclosure are provided in the following description, are clear in the following description, or are understandable through practice of the present disclosure.

### BRIEF DESCRIPTION OF DRAWINGS

The earlier described and/or additional aspects and advantages of the present disclosure will be clear and comprehensible from the following description of the embodiments with reference to the accompanying drawings, in which

FIG. 1 is a schematic diagram illustrating an LED package structure according to an embodiment of the present disclosure;

FIG. 2 is a schematic diagram illustrating an LED package structure according to another embodiment of the present disclosure;

FIG. 3 is a schematic diagram illustrating an LED package structure according to another embodiment of the present disclosure;

FIG. 4 is a schematic diagram illustrating an LED package structure according to another embodiment of the present disclosure;

FIG. 5 is a schematic diagram illustrating an LED package structure according to another embodiment of the present disclosure;

FIG. 6 is a schematic diagram illustrating an LED package structure according to another embodiment of the present disclosure;

FIG. 7 is a schematic diagram illustrating an LED package structure according to another embodiment of the present disclosure;

FIG. 8 is a schematic diagram illustrating an LED package structure according to another embodiment of the present disclosure;

FIG. 9 is a schematic diagram illustrating an LED package structure according to another embodiment of the present disclosure;

FIG. 10 is a schematic diagram illustrating an LED package structure according to another embodiment of the present disclosure;

FIG. 11 is a schematic diagram illustrating an LED package structure according to another embodiment of the present disclosure;

FIG. 12 is a schematic diagram illustrating an LED package structure according to another embodiment of the present disclosure;

FIG. 13 is a schematic diagram illustrating an LED package structure according to another embodiment of the present disclosure;

FIG. 14 is a schematic diagram illustrating an LED package structure according to another embodiment of the present disclosure;

FIG. 15 is a schematic diagram illustrating an LED package structure according to another embodiment of the present disclosure;

FIG. 16 is a schematic diagram illustrating an LED package structure according to another embodiment of the present disclosure;

FIG. 17 is a schematic diagram illustrating an LED package structure according to another embodiment of the present disclosure;

FIG. 18 is a schematic diagram illustrating an LED package structure according to another embodiment of the present disclosure;

FIG. 19 is a schematic flowchart illustrating a method for manufacturing an LED package structure according to an embodiment of the present disclosure; and

FIG. 20 is a schematic flowchart illustrating a method for manufacturing an LED package structure according to another embodiment of the present disclosure.

### LIST OF REFERENCE NUMERALS

Substrate: 1100; second surface: 1110; insulating layer: 1120; first surface: 1130; LED chip: 1200; groove body: 1300; conductive hole: 1301; conductive material: 1310; second circuit layer: 1320; bottom wall: 1311; side wall: 1312; encapsulant: 1400.

### DETAILED DESCRIPTION

Embodiments of the present disclosure are described in detail below. Examples of the embodiments are illustrated in the accompanying drawings. Reference numerals that keep the same or similar from beginning to end represent the same or similar elements or elements with same or similar functions. The embodiments described below with reference to the accompanying drawings are examples and are merely intended to explain the present disclosure, and should not be construed as a limitation on the present disclosure.

In the description of the present disclosure, it should be understood that directions or position relationships indicated by direction-related description “up”, “down”, “front”, “rear”, “left”, “right”, and the like are based on directions or position relationships shown by the accompanying drawings, which are used only for describing the present disclosure and for description simplicity, but do not indicate or imply that an indicated apparatus or element must have a specific direction or must be constructed and operated in a specific direction. Therefore, this cannot be understood as a limitation on the present disclosure.

In the description of the present disclosure, “several” means one or more, and “a plurality of” means two or more. “Greater than”, “less than”, “exceeding”, and the like are understood as excluding the current number, and “above”, “below”, “within”, and the like are understood as including the current number. The terms “first” and “second” if mentioned are merely intended to distinguish between technical features, and shall not be understood as an indication or implication of relative importance or an implicit indication of the number of indicated technical features or an implicit indication of the sequence of indicated technical features.

In the description of the present disclosure, unless otherwise explicitly defined, the terms such as “dispose”, “mount” and “connect” should be understood in a broad sense. A person skilled in art can properly determine the specific meanings of the above terms in the present disclosure with reference to the specific content of the technical solution.

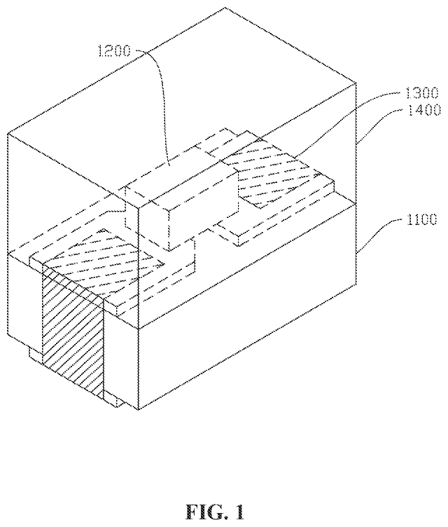

FIG. 1 is a schematic diagram of an LED package structure according to an embodiment of the present disclosure. The LED package structure shown in FIG. 1 includes at least a substrate 1100, an LED chip 1200, a groove body 1300, and an encapsulant 1400. FIG. 1 shows a perspective view of the LED package structure. The groove body 1300 is provided inside the substrate 1100, the LED chip 1200 is disposed above the substrate 1100, and the encapsulant 1400 is further laid on the substrate 1100. The encapsulant 1400 is made of a light-transmitting material or a fluorescent encapsulant, and is configured to protect a circuit above the substrate 1100 and protect the LED chip 1200.

In some embodiments, the LED package structure includes the substrate 1100 and the LED chip 1200, where the substrate includes a second surface 1110, an insulating layer 1120, and a first surface 1130; a first circuit layer is on the first surface 1130, a second circuit layer is on the second surface 1110, and the insulating layer 1120 is between the first circuit layer and the second circuit layer; the LED chip 1200 is disposed on the second surface 1110; the substrate 1100 further includes a first groove body and a second groove body, two ends of the first groove body are connected to the second surface 1110 and the first surface 1130 respectively, and two ends of the second groove body are connected to the second surface 1110 and the first surface 1130 respectively; the first groove body is filled with a conductive material 1310, a side wall 1312 (a part of the conductive material exposed at a side face in the groove body) and a bottom wall 1311 (a part of the conductive material exposed at the first surface in the groove body) of the first groove body each include a wetting structure (soldering side); the second groove body is filled with the conductive material 1310, and a side wall 1312 and a bottom wall 1311 of the second groove body each include a wetting structure.

The LED package structure in an embodiment according to the first aspect of the present disclosure includes a first surface 1130 and at least one side face adjacent to the first surface. The LED package structure further includes a first soldering side disposed on the first surface 1130; and a second soldering side electrically connected to the first soldering side and disposed on the side face.

In some embodiments, side faces may be adjacent or opposite to each other.

In some embodiments, the LED package structure includes a first soldering side including a first soldering layer; and a second soldering side connected to the first soldering side and including a second soldering layer.

In some embodiments, the LED package structure further includes the substrate 1100 and an LED chip; the substrate 1100 includes a second surface 1110, an insulating layer 1120, a first surface 1130, and four side faces; a first circuit layer is on the first surface 1130, a second circuit layer is on the second surface 1110, and the insulating layer 1120 is between the first circuit layer and the second circuit layer; the four side faces are all adjacent to the first surface 1130; the LED chip is disposed on the second surface 1110; the substrate 1100 further includes a first groove body and a second groove body, and the first groove body is filled with a conductive material; the conductive material is exposed at the first surface to form a first soldering side (for example, the conductive material is exposed at the first surface to directly form the first soldering side, or the conductive material is exposed at the first surface and forms the first soldering side jointly with the first circuit layer); the conductive material is exposed at the side face to form a second soldering side, or the conductive material is exposed at the side face and is electrically connected to the second soldering side (for example, the second soldering side may be plated on the side face to be electrically connected to the conductive material); the second groove body is filled with a conductive material; the conductive material is exposed at the first surface to form a third soldering side (for example, the conductive material is exposed at the first surface to directly form the third soldering side, or the conductive material is exposed at the first surface and forms the third soldering side jointly with the first circuit layer); and the conductive material is exposed at the side face to form a fourth soldering face, or the conductive material is exposed at the side face and is electrically connected to the fourth soldering side. It should be noted that the above side faces may be the same side face or different side faces.

In some embodiments, the first groove body and the second groove body may pass through the substrate 1100, or may pass through the first surface 1130 and the insulating layer 1120. If a groove body that does not pass through the substrate 1100 is used, it is unnecessary to perform processes such as cutting and grinding on a non-penetrated surface during processing of the LED package structure, thereby improving the production efficiency. The groove body may be a groove body formed after cutting the conductive holes (such as through holes or blind holes) of the substrate. For details, reference can be made to the description below.

In some embodiments, the LED package structure further includes a (2N−1)^{th} soldering side disposed on the first surface 1130; and a (2N)^{th} soldering side disposed on the side face; where N is a positive integer greater than or equal to 2.

In some embodiments, the substrate 1100 further includes an N^{th} groove body, where the N^{th} groove body is filled with a conductive material; the conductive material is exposed at the first surface to form the (2N−1)^{th} soldering side (for example, the conductive material is exposed at the first surface to directly form the (2N−1)^{th} soldering side, or the conductive material is exposed at the first surface and forms the (2N−1)^{th} soldering side jointly with the first circuit layer); and the conductive material is exposed at the side face to form the (2N)^{th} soldering side, or the conductive material is exposed at the side face and is electrically connected to the (2N)^{th} soldering side.

In some embodiments, as shown in FIG. 1, there are 2 groove bodies. There may be 3, 4, 5, 6 or another number of groove bodies to adapt to different LED chips.

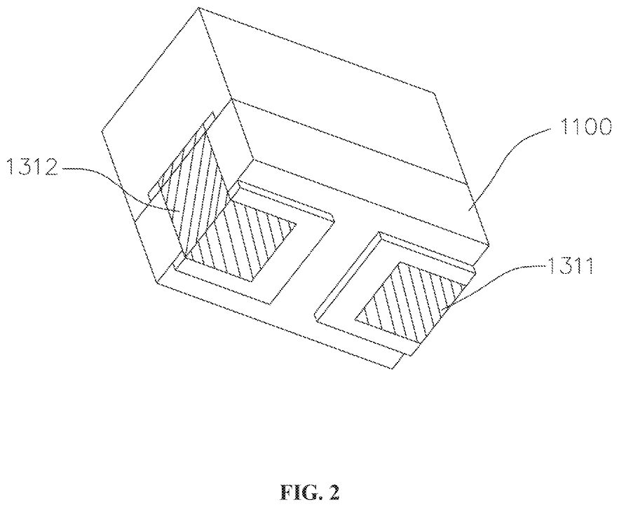

FIG. 2 is a schematic diagram of an LED package structure according to another embodiment of the present disclosure. The LED package structure shown in FIG. 2 includes at least a substrate 1100, and a side wall 1312 and a bottom wall 1311 of a groove body 1300, where the side wall 1312 is a part of a conductive material exposed at a side face in the groove body and the bottom wall 1311 is a part of the conductive material exposed at a first surface 1130 in the groove body. As shown in FIG. 2, the side wall 1312 and the bottom wall 1311 of the groove body 1300 in the LED package structure are both formed by filling the groove body 1300 with a conductive material 1310. Therefore, both the side wall 1312 and the bottom wall 1311 can allow for wetting, which increases the wetting area of the LED package structure, and improves the stability of the LED package structure in use. For example, when the LED package structure has a length less than or equal to 0.65 mm, a width less than or equal to 0.35 mm, and a height less than or equal to 0.25 mm, the LED package structure according to the embodiments of the present disclosure can solve the problem of insufficient package soldering strength caused by a small size and a small wetting area of the package structure.

In some embodiments, the substrate 1100 further includes a third groove body and a fourth groove body, where two ends of the third groove body are connected to a first surface and a second surface respectively, and two ends of the fourth groove body are connected to the first surface and the second surface respectively; the third groove body is filled with a conductive material 1310, a side wall 1312 and a bottom wall 1311 of the third groove body each include a wetting structure; the fourth groove body is filled with the conductive material 1310, and a side wall 1312 and a bottom wall 1311 of the fourth groove body each include a wetting structure.

In some embodiments, the substrate 1100 further includes a third groove body and a fourth groove body, where two ends of the third groove body are connected to a first surface and a second surface respectively, and two ends of the fourth groove body are connected to the first surface and the second surface respectively; the third groove body is filled with a conductive material, a side wall of the third groove body is connected to a fifth soldering side, and a bottom wall thereof is connected to a sixth soldering side; the fourth groove body is filled with a conductive material, a side wall of the fourth groove body is connected to a seventh soldering side, and a bottom wall thereof is connected to an eighth soldering side.

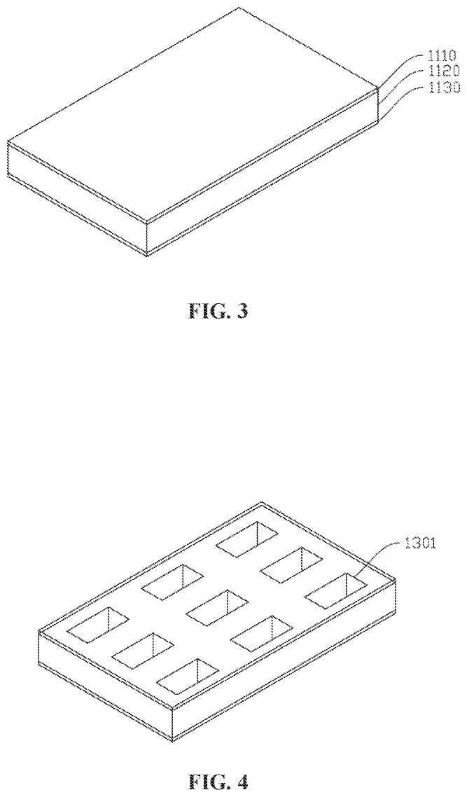

FIG. 3 is a schematic diagram of an LED package structure according to another embodiment of the present disclosure. The LED package structure shown in FIG. 3 includes at least a second surface 1110, an insulating layer 1120, and a first surface 1130. The second surface 1110, the insulating layer 1120, and the first surface 1130 are sequentially arranged, the second surface 1110 is provided with a second conductive layer, and the first surface 1130 is provided with a first conductive layer. The first conductive layer may be processed to form a first circuit layer, and the second conductive layer may be processed to form a second circuit layer.

FIG. 4 is a schematic diagram of an LED package structure according to another embodiment of the present disclosure. The LED package structure shown in FIG. 4 includes at least conductive holes 1301. As shown in FIG. 4, a substrate 1100 is provided with the conductive holes 1301. The conductive holes 1301 may be through holes. The conductive holes 1301 need to pass through the substrate 1100, such that a conductive material is exposed at a first surface 1130 and a second surface 1110 of the substrate 1100; the conductive holes 1301 may alternatively be blind holes, and the conductive holes 1301 need to pass through an insulating layer 1120 and the first surface 1130, such that the conductive material is exposed at the first surface 1130 of the substrate 1100.

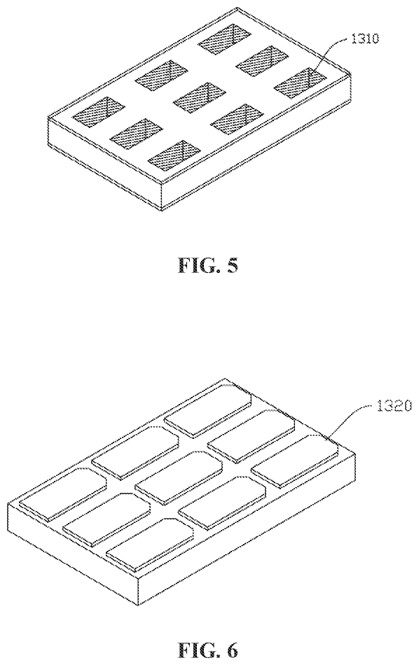

FIG. 5 is a schematic diagram of an LED package structure according to another embodiment of the present disclosure. The LED package structure shown in FIG. 5 includes at least a conductive material 1310. As shown in FIG. 5, conductive holes 1301 are filled with the conductive material 1310. The conductive material 1310 includes one or more of copper, silver, gold, palladium, and tin. The conductive material 1310 allows for wetting.

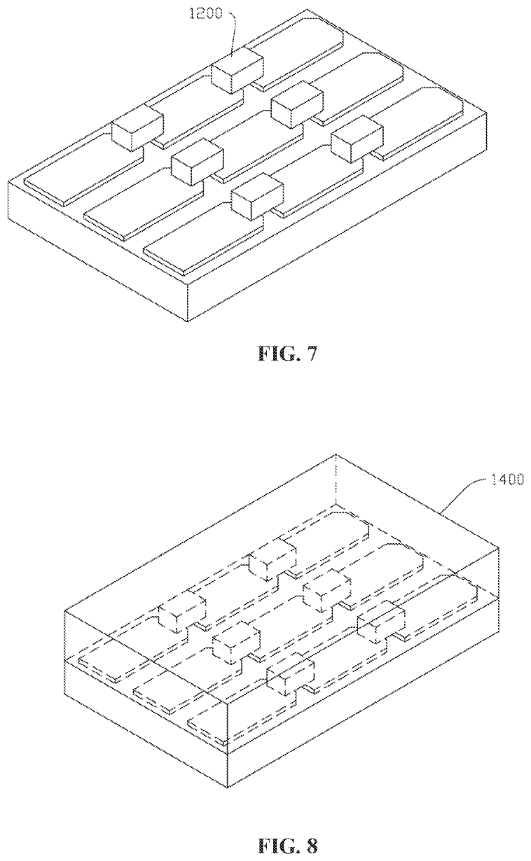

FIG. 6 and FIG. 7 are schematic diagrams of an LED package structure according to another embodiment of the present disclosure. The LED package structure shown in FIG. 6 and FIG. 7 includes at least an LED chip 1200. As shown in FIG. 6 and FIG. 7, the LED chip 1200 is attached above a second circuit layer 1320.

FIG. 8 is a schematic diagram of an LED package structure according to another embodiment of the present disclosure. The LED package structure shown in FIG. 8 includes at least an encapsulant 1400. As shown in FIG. 8, the encapsulant 1400 is laid above a substrate 1100. After being solidified, the encapsulant 1400 can protect the LED package structure.

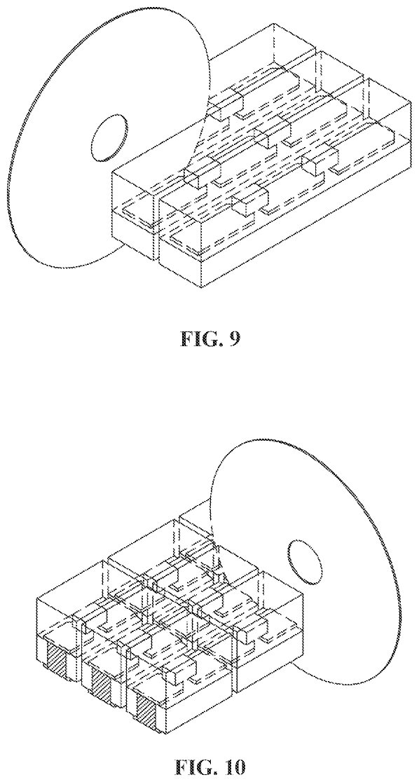

FIG. 9 and FIG. 10 are schematic diagrams of an LED package structure according to another embodiment of the present disclosure. As shown in FIG. 9 and FIG. 10, the LED package structure is cut to obtain the LED package structures shown in FIG. 1 and FIG. 2. For example, conductive holes 1301 may be penetrated and cut, such that a side face of the LED package structure is formed and a conductive material is exposed at the side face to form a second soldering side. It should be noted that the above groove body 1300 is formed after the conductive holes 1301 are cut.

In some embodiments, the LED package structure has a length less than or equal to 0.65 mm, a width less than or equal to 0.35 mm, and a height less than or equal to 0.25 mm.

In some embodiments, a conductive material 1310 includes one or more of copper, silver, gold, palladium, and tin.

In some embodiments, the LED package structure further includes an encapsulant 1400, where the encapsulant 1400 is laid on an LED chip 1200.

In some embodiments, a first circuit layer is provided with a first circuit, and a second circuit layer 1320 is provided with a second circuit.

In some embodiments, the conductive material 1310 connects the first circuit to the second circuit.

An LED module in an embodiment according to the second aspect of the present disclosure includes at least two LED package structures according to the first aspect.

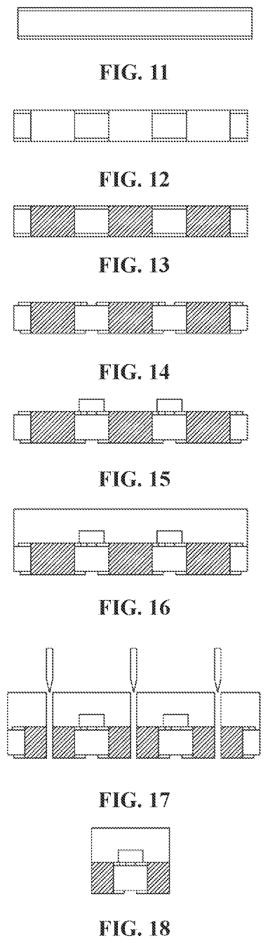

In some embodiments, FIG. 11 to FIG. 18 are schematic diagrams of an LED package structure according to another embodiment of the present disclosure. FIG. 11 to FIG. 18 show two-dimensional images corresponding to the LED package structures shown in FIG. 3 to FIG. 10. Details are omitted here for simplicity.

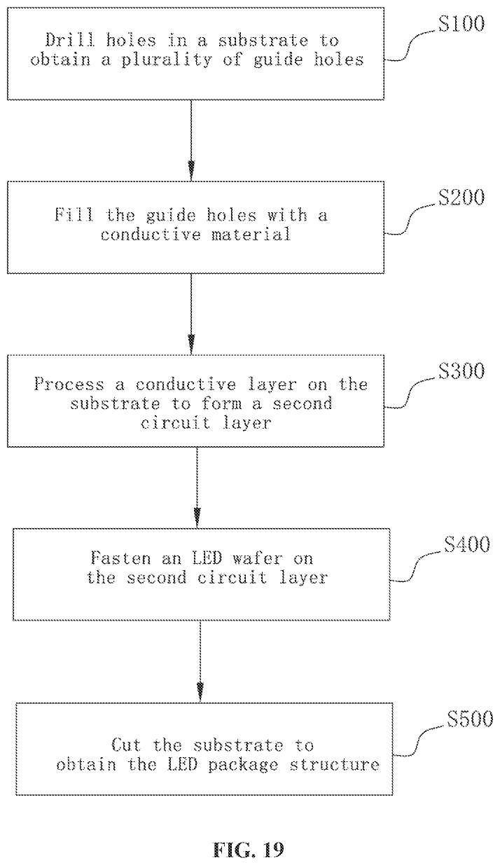

As shown in FIG. 19, a method for manufacturing an LED package structure in an embodiment according to the third aspect of the present disclosure includes at least the following steps: S100: drilling holes in a substrate to obtain conductive holes; S200: filling the conductive holes with a conductive material; S300: processing a conductive layer on the substrate to form a second circuit layer; S400: attaching an LED chip on the second circuit layer; and S500: cutting the substrate to obtain the LED package structure according to the first aspect.

At step S100, holes are drilled in a substrate to obtain a plurality of conductive holes.

In some embodiments, holes are drilled in the substrate to obtain conductive holes. The conductive holes may have any shapes and are configured to connect circuits on the upper and lower surfaces of the substrate. For example, as shown in FIG. 4, a plurality of rectangular conductive holes may be drilled on the substrate to form a conductive hole array. The conductive holes may be through holes or blind holes.

At step S200, the conductive holes are filled with a conductive material, where the conductive material may be exposed at a first surface and a second surface of the substrate, or may be exposed at the first surface but not from the second surface. The conductive material is exposed at the first surface of the substrate and forms a first soldering side jointly with a first circuit layer.

In some embodiments, the conductive holes are filled with a conductive material, and conductive layers are formed on the upper surface and the lower surface of the substrate. The conductive material is usually one or more of copper, silver, gold, palladium, and tin. The filled conductive material may be slightly higher than the substrate to facilitate subsequent processing.

At step S300, a conductive layer on the substrate is processed to form a second circuit layer.

In some embodiments, a conductive layer on the substrate is processed to form the second circuit layer. The processing may be implemented by exposure, development, etching, electroplating, etc. In some embodiments, the second circuit layer is processed and formed on the upper surface (the second surface) of the substrate; and the first circuit layer is processed and formed on the lower surface (the first surface) of the substrate. In some embodiments, referring to FIG. 3, a second surface 1110 of the substrate is provided with a second conductive layer, and a first surface 1130 is provided with a first conductive layer. The first conductive layer may be processed to form the first circuit layer, and the second conductive layer may be processed to form the second circuit layer.

At step S400, an LED chip is attached on the second circuit layer.

In some embodiments, an LED chip is attached on the second circuit layer. Attaching methods include but are not limited to soldering. Two contacts of the LED chip are soldered on the second circuit layer to connect the LED chip to the second circuit layer. In some embodiments, the second circuit layer is disposed on the upper surface (the second surface) of the substrate.

At step S500, the substrate is cut to obtain the LED package structure according to the first aspect.

In some embodiments, the substrate is cut to obtain the LED package structure in the embodiments according to the first aspect. Cutting methods include but are not limited to cutter-based cutting and laser cutting. It should be noted that the order of cutting may be selected as required, which is not limited in the present application. During cutting, the conductive material needs to be penetrated to form a cutting surface.

In some embodiments, after an LED chip 1200 is attached on the second circuit layer, the method further includes: covering the LED chip with a transparent or semi-transparent encapsulant or a fluorescent encapsulant. In some embodiments, the encapsulant may be laid above the substrate, such that the encapsulant covers the upper part of the substrate and the LED chip.

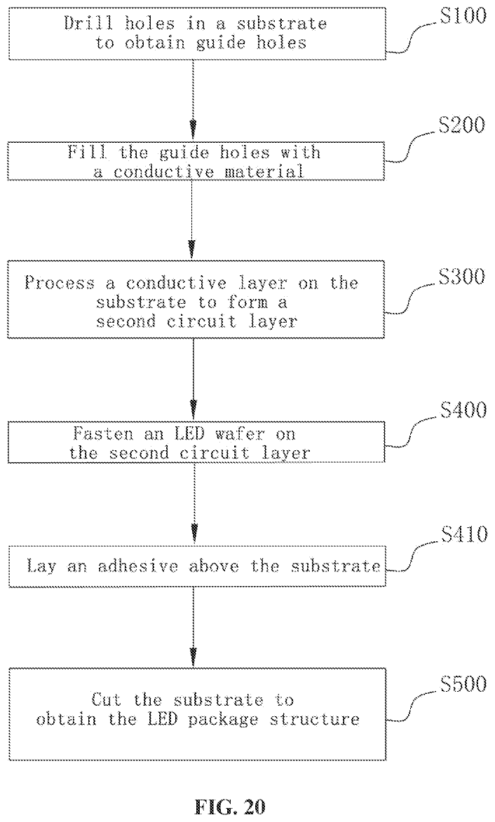

That is, as shown in FIG. 20, in some embodiments, a method for manufacturing an LED package structure includes at least the following steps:

S100: Drilling holes in a substrate to obtain conductive holes.

S200: Filling the conductive holes with a conductive material.

S300: Processing a conductive layer on the substrate to form a second circuit layer.

S400: Attaching an LED chip on the second circuit layer.

S410: Laying an encapsulant above the substrate.

S500: Cutting the substrate to obtain the LED package structure according to the first aspect.

An LED light source in an embodiment according to the fourth aspect of the present disclosure includes at least one LED package structure according to the first aspect, or includes at least one LED module according to the second aspect.

The embodiments of the present disclosure are described in detail above with reference to the accompanying drawings, but the present disclosure is not limited to the above embodiments. Within the scope of knowledge possessed by a person of ordinary skill in the art, various changes may also be made without departing from the purpose of the present disclosure.

The apparatus embodiments described above are only schematic, where units described as separate components may or may not be physically separated, i.e., the components may be located in one position, or may be distributed over a plurality of network units. Some or all of the modules may be selected according to actual needs to achieve the objective of the solutions of the embodiments.

In the description of the present specification, description with reference to the terms such as “one embodiment”, “some embodiments”, “schematic embodiment”, “example”, “specific example”, or “some examples” mean that specific features, structures, materials or characteristics described with reference to the embodiment or example are included in at least one embodiment or example of the present disclosure. In the present specification, the illustrative expressions of the above terms do not necessarily refer to the same embodiment or example. Furthermore, the specific features, structures, materials or characteristics described may be combined in any one or more embodiments or examples in a proper way.

Although the embodiments of the present disclosure have been shown and described, a person of ordinary skill in the art can understand that various changes, modifications, replacements and variations can be made to these embodiments without departing from the principles and purposes of the present disclosure. The scope of the present disclosure is subject to the claims and equivalents thereof

What is claimed is:

1. An LED package structure, comprising:
a first surface;
at least one side face adjacent to the first surface;
a first soldering side disposed on the first surface; and
a second soldering side electrically connected to the first soldering side and disposed on the side face.

2. The LED package structure of claim 1, further comprising: a substrate and an LED chip; wherein
the substrate comprises a first circuit layer, an insulating layer, and a second circuit layer, the first circuit layer is on the first surface, the second circuit layer is on a second surface, and the insulating layer is between the first circuit layer and the second circuit layer;
the LED chip is disposed on the second circuit layer and is electrically connected to the second circuit layer; and
the substrate further comprises a first groove body, and the first groove body is filled with a conductive material;
the conductive material is exposed at the first surface to form the first soldering side, or the conductive material is exposed at the first surface and is electrically connected to the first soldering side; and
the conductive material is exposed at the side face to form the second soldering side, or the conductive material is exposed at the side face and is electrically connected to the second soldering side.

3. The LED package structure of claim 2, further comprising:
a (2N−1)^{th} soldering side disposed on the first surface; and
a (2N)^{th} soldering side disposed on the side face;
wherein N is a positive integer greater than or equal to 2.

4. The LED package structure of claim 3, wherein the substrate further comprises:
an N^{th} groove body, wherein the N^{th} groove body is filled with a conductive material; the conductive material is exposed at the first surface to form the (2N−1)^{th} soldering side, or the conductive material is exposed at the first surface and is electrically connected to the (2N−1)^{th} soldering side; and the conductive material is exposed at the side face to form the (2N)^{th} soldering side, or the conductive material is exposed at the side face and is electrically connected to the (2N)^{th} soldering side.

5. The LED package structure of claim 2, wherein the conductive material comprises one or more of copper, silver, gold, palladium, and tin.

6. The LED package structure of claim 5, further comprising:
an encapsulant covering the LED chip.

7. The LED package structure of claim 6, wherein the first circuit layer is provided with a first circuit, and the second circuit layer is provided with a second circuit; and the conductive material is configured for connecting the first circuit to the second circuit.

8. A method for manufacturing an LED package structure, comprising:
drilling holes in a substrate to obtain a plurality of conductive holes;
filling the conductive holes with a conductive material, so that the conductive material is exposed at a first surface of the substrate to form a first soldering side;
processing a conductive layer on the substrate to form a second circuit layer;
attaching an LED chip on the second circuit layer and connecting the LED chip to the second circuit layer; and
cutting the substrate to expose the conductive material from a side face of the LED package structure to form a second soldering side.

9. The method for manufacturing an LED package structure of claim 8, wherein after attaching an LED chip on the second circuit layer, the method further comprises:
covering the LED chip with a transparent or semi-transparent encapsulant or a fluorescent encapsulant.

10. An LED light source, comprising at least one LED package structure, the at least one LED package structure comprising:
a first surface;
at least one side face adjacent to the first surface;
a first soldering side disposed on the first surface; and
a second soldering side electrically connected to the first soldering side and disposed on the side face.

11. The LED light source of claim 10, the at least one LED package structure further comprises: a substrate and an LED chip; wherein
the substrate comprises a first circuit layer, an insulating layer, and a second circuit layer, the first circuit layer is on the first surface, the second circuit layer is on a second surface, and the insulating layer is between the first circuit layer and the second circuit layer;
the LED chip is disposed on the second circuit layer and is electrically connected to the second circuit layer; and
the substrate further comprises a first groove body, and the first groove body is filled with a conductive material;
the conductive material is exposed at the first surface to form the first soldering side, or the conductive material is exposed at the first surface and is electrically connected to the first soldering side; and
the conductive material is exposed at the side face to form the second soldering side, or the conductive material is exposed at the side face and is electrically connected to the second soldering side.

12. The LED light source of claim 11, the at least one LED package structure further comprises:
a (2N−1)^{th} soldering side disposed on the first surface; and
a (2N)^{th} soldering side disposed on the side face;
wherein N is a positive integer greater than or equal to 2.

13. The LED light source of claim 12, wherein the substrate further comprises:
an N^{th} groove body, wherein the N^{th} groove body is filled with a conductive material; the conductive material is exposed at the first surface to form the (2N−1)^{th} soldering side, or the conductive material is exposed at the first surface and is electrically connected to the (2N−1)^{th} soldering side; and the conductive material is exposed at the side face to form the (2N)^{th} soldering side, or the conductive material is exposed at the side face and is electrically connected to the (2N)^{th} soldering side.

14. The LED light source of claim 11, wherein the conductive material comprises one or more of copper, silver, gold, palladium, and tin.

15. The LED light source of claim 14, the at least one LED package structure further comprises:
an encapsulant covering the LED chip.

16. The LED light source of claim 15, wherein the first circuit layer is provided with a first circuit, and the second circuit layer is provided with a second circuit; and the conductive material is configured for connecting the first circuit to the second circuit.
